(19) United States
(12) Patent Application Publication
(10) Pub. No.: US 2025/0268107 A1
(43) Pub. Date: Aug. 21, 2025

(54) COMPOSITE SUBSTRATE

(71) Applicant: NGK INSULATORS, LTD., Nagoya-shi (JP)

(72) Inventors: Yudai UNO, Nagoya-shi (JP); Tomoyoshi TAI, Inazawa-shi (JP); Masahiko NAMERIKAWA, Seto-shi (JP)

(21) Appl. No.: 19/198,423

(22) Filed: May 5, 2025

Related U.S. Application Data
(63) Continuation of application No. PCT/JP2023/041547, filed on Nov. 17, 2023.

(30) Foreign Application Priority Data
Nov. 18, 2022 (JP) 2022-185043

(51) Int. Cl. H10N 30/50; H10N 30/097; H10N 30/20; H10N 30/853

(52) U.S. Cl. CPC H10N 30/50; H10N 30/853; H10N 30/097; H10N 30/20

(57) ABSTRACT

A composite substrate including: a first piezoelectric layer; a second piezoelectric layer that is disposed to be stacked on the first piezoelectric layer; and a support substrate that supports the first piezoelectric layer and the second piezoelectric layer, an amorphous layer being formed on a bonding interface between at least one of the first piezoelectric layer and the second piezoelectric layer and another layer, the second piezoelectric layer, the first piezoelectric layer, and the support substrate being stacked in this order.

### CROSS-REFERENCE TO RELATED APPLICATION

This application is a continuation application of PCT/JP2023/041547, filed on Nov. 17, 2023, which claims the benefit of priority of Japanese Patent Application No. 2022-185043, filed on Nov. 18, 2022, the entire contents of which are incorporated herein by reference.

### 1. TECHNICAL FIELD

The present invention relates to a composite substrate.

### 2. DESCRIPTION OF RELATED ART

In the related art, piezoelectric actuators that cause electromechanical conversion films to vibrate have been put into practical use in liquid droplet ejection heads of inkjet recording apparatuses and the like. Furthermore, applications to other purposes (for example, MEMS mirror devices for head-up displays) have also been expected in recent years.

As a method of manufacturing a piezoelectric actuator in the related art, a technique of producing a composite substrate in which a piezoelectric element is caused to adhere to a silicon substrate via a metal layer and configuring a piezoelectric actuator using the composite substrate is known (Patent Literature 1: Japanese Patent Laid-Open No. 2007-271788). Moreover, a technique of producing a composite substrate in which a piezoelectric layer of PZT or the like is formed on a silicon substrate by a sputtering method and configuring a piezoelectric actuator using the composite substrate is also known (Patent Literature 2: Japanese Patent Laid-Open No. 2014-225596).

In the composite substrate produced using the method disclosed in Patent Literature 1, the piezoelectric element cannot be formed to be very thin in order to enable the piezoelectric element to adhere to the silicon substrate. Therefore, there is a problem that it is difficult to achieve size reduction of the piezoelectric actuator. On the other hand, the composite substrate produced using the method disclosed in Patent Literature 2 is advantageous for size reduction of the piezoelectric actuator since the piezoelectric layer can be formed to be thin in the film formation. However, since the film formation is performed in a high-temperature environment, deformation such as warpage is likely to occur in the composite substrate due to a change in temperature after the film formation. Therefore, there is a problem that it is difficult to increase the thickness of the piezoelectric layer.

In a case where the amount of operation required for a piezoelectric layer is relatively large as in a piezoelectric actuator of a MEMS mirror device, for example, it is necessary to achieve both size reduction and a piezoelectric property. However, it is difficult to realize this by the methods in Patent Literatures 1 and 2.

The present invention was made in view of the above circumstances, and a main object thereof is to provide a composite substrate that includes piezoelectric layers capable of achieving both size reduction and a piezoelectric property.

### SUMMARY OF THE INVENTION

A composite substrate according to a first aspect of the present invention includes: a first piezoelectric layer; and a second piezoelectric layer that is disposed to be stacked on the first piezoelectric layer, and an amorphous layer is formed on a bonding interface between at least one of the first piezoelectric layer and the second piezoelectric layer and another layer.

A composite substrate according to a second aspect of the present invention includes: a first piezoelectric layer; and a second piezoelectric layer that is disposed to be stacked on the first piezoelectric layer, and at least one of the first piezoelectric layer and the second piezoelectric layer is directly bonded to another layer.

According to the present invention, it is possible to provide a composite substrate that includes piezoelectric layers capable of achieving both size reduction and a piezoelectric property.

### BRIEF DESCRIPTION OF THE DRAWINGS

FIG. 1 is a schematic sectional view illustrating an overview configuration of a composite substrate according to a first embodiment of the present invention.

FIG. 2 is a schematic sectional view illustrating an overview configuration of a composite substrate according to a second embodiment of the present invention.

FIG. 3 is a schematic sectional view illustrating an overview configuration of a composite substrate according to a third embodiment of the present invention.

FIG. 4 is a schematic sectional view illustrating an overview configuration of a composite substrate according to a fourth embodiment of the present invention.

FIG. 5 is a schematic sectional view illustrating an overview configuration of a composite substrate according to a fifth embodiment of the present invention.

FIG. 6 is a diagram illustrating an example of a case where an opening portion is provided in a support substrate in the composite substrate according to the fifth embodiment of the present invention.

FIG. 7 is a diagram illustrating an example of a case where the opening portion is provided in the support substrate in the composite substrate according to the fifth embodiment of the present invention.

FIG. 8 is a diagram illustrating an example of a case where a hollow portion is provided in the support substrate in the composite substrate according to the fifth embodiment of the present invention.

FIG. 9 is a diagram illustrating an example of a case where a sacrificial layer is provided in the support substrate in the composite substrate according to the fifth embodiment of the present invention.

FIG. 10 is a schematic sectional view illustrating an overview configuration of a composite substrate according to a sixth embodiment of the present invention.

FIGS. 11A, 11B and 11C are diagrams illustrating examples of manufacturing processes of the composite substrate according to the second embodiment of the present invention.

FIG. 12A is a sectional TEM observation photograph (50,000 folds) of a composite substrate in an example.

FIG. 12B is a sectional TEM observation photograph (400,000 folds) of the composite substrate in the example.

FIG. 12C is a sectional TEM observation photograph (2,000,000 folds) of the composite substrate in the example.

### DESCRIPTION OF PREFERRED EMBODIMENTS

Although embodiments of the present invention will be described below with reference to the drawings, the present invention is not limited to these embodiments. Also, although the width, the thickness, the shape, and the like of each component may be schematically represented in the drawings as compared with those in the embodiments for more clear explanation, these are just examples and are not intended to limit interpretation of the present invention.

### A. Composite Substrate

### (A-1) First Embodiment

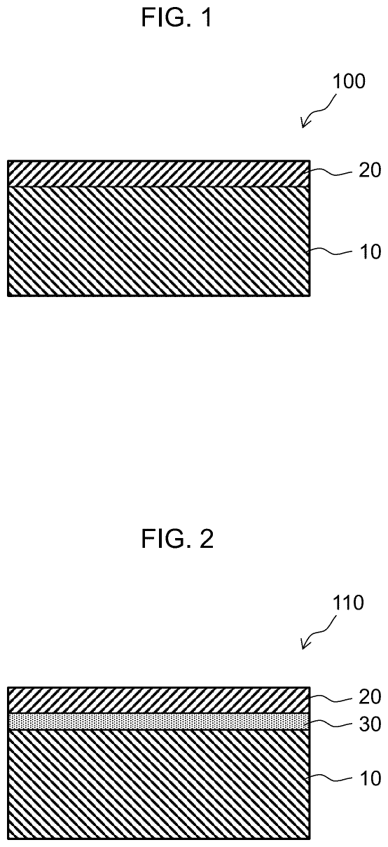

FIG. 1 is a schematic sectional view illustrating an overview configuration of a composite substrate according to a first embodiment of the present invention. A composite substrate 100 includes a first piezoelectric layer 10 and a second piezoelectric layer 20 that is disposed to be stacked on the first piezoelectric layer 10. Polarization directions of the first piezoelectric layer 10 and the second piezoelectric layer 20 are preferably mutually opposite directions, and these forms a bimorph structure.

In the composite substrate 100, the first piezoelectric layer 10 and the second piezoelectric layer 20 are directly bonded to each other, and an amorphous layer generated at the time of the bonding is formed at a bonding interface therebetween. Note that specific examples and a bonding method of the first piezoelectric layer 10 and the second piezoelectric layer 20 will be described later.

### (A-2) Second Embodiment

FIG. 2 is a schematic sectional view illustrating an overview configuration of a composite substrate according to a second embodiment of the present invention. A composite substrate 110 further includes an electrode layer 30 disposed between a first piezoelectric layer 10 and a second piezoelectric layer 20 as compared with the composite substrate 100 described in the first embodiment. The electrode layer 30 is constituted using a conductive material such as metal, for example.

In the composite substrate 110, the first piezoelectric layer 10 or the second piezoelectric layer 20 and the electrode layer 30 are directly bonded to each other, and an amorphous layer generated at the time of the bonding is formed at a bonding interface therebetween. Note that a specific example and a bonding method of the electrode layer 30 will be described later.

### (A-3) Third Embodiment

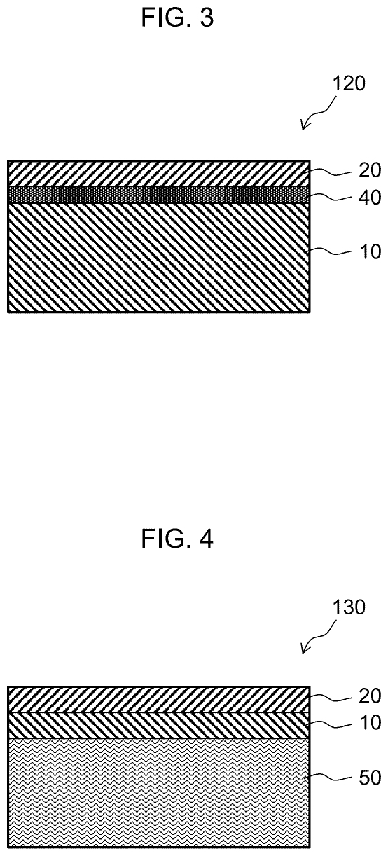

FIG. 3 is a schematic sectional view illustrating an overview configuration of a composite substrate according to a third embodiment of the present invention. A composite substrate 120 includes a bonding layer 40, instead of the electrode layer 30, disposed between a first piezoelectric layer 10 and a second piezoelectric layer 20 as compared with the composite substrate 110 described in the second embodiment. The bonding layer 40 is constituted using an amorphous body, for example.

In the composite substrate 120, the first piezoelectric layer 10 or the second piezoelectric layer 20 and the bonding layer 40 are directly bonded to each other, and an amorphous layer generated at the time of the bonding is formed at a bonding interface therebetween. Note that a specific example and a bonding method of the bonding layer 40 will be described later.

### (A-4) Fourth Embodiment

FIG. 4 is a schematic sectional view illustrating an overview configuration of a composite substrate according to a fourth embodiment of the present invention. A composite substrate 130 further includes a support substrate 50 that supports a first piezoelectric layer 10 and a second piezoelectric layer 20 as compared with the composite substrate 100 described in the first embodiment. The support substrate 50 is constituted using an arbitrary material.

In the composite substrate 130, the first piezoelectric layer 10 and the second piezoelectric layer 20 are directly bonded to each other, and an amorphous layer generated at the time of the bonding is formed at a bonding interface therebetween. Similarly, the first piezoelectric layer 10 and the support substrate 50 are directly bonded to each other, and an amorphous layer generated at the time of the bonding is formed at a bonding interface therebetween. Note that a specific example and a bonding method of the support substrate 50 will be described later.

### (A-5) Fifth Embodiment

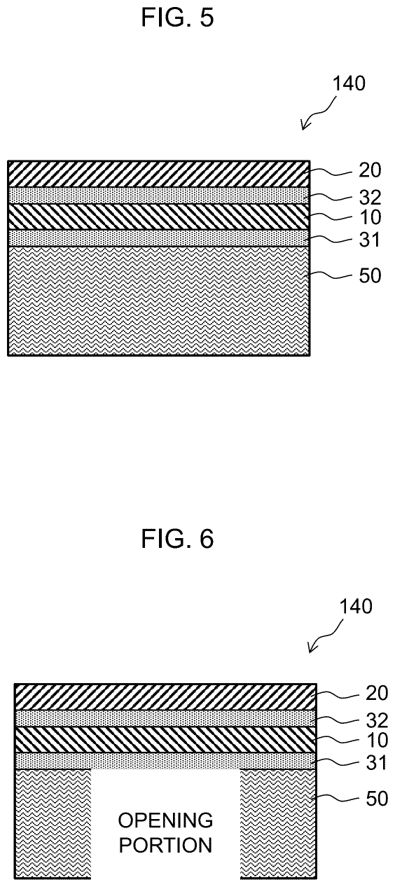

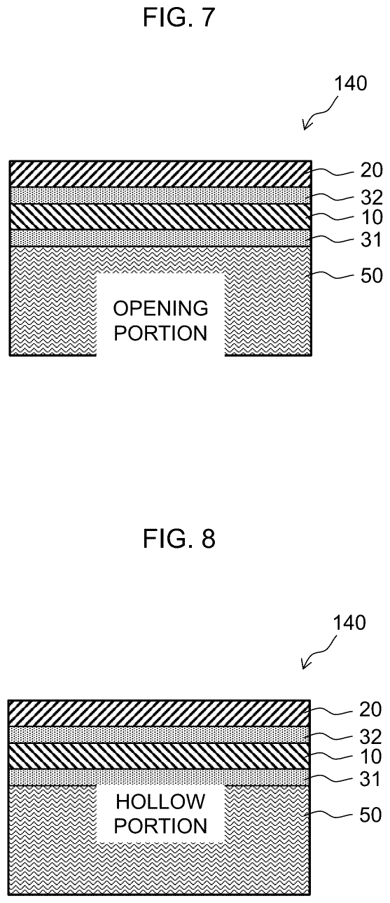

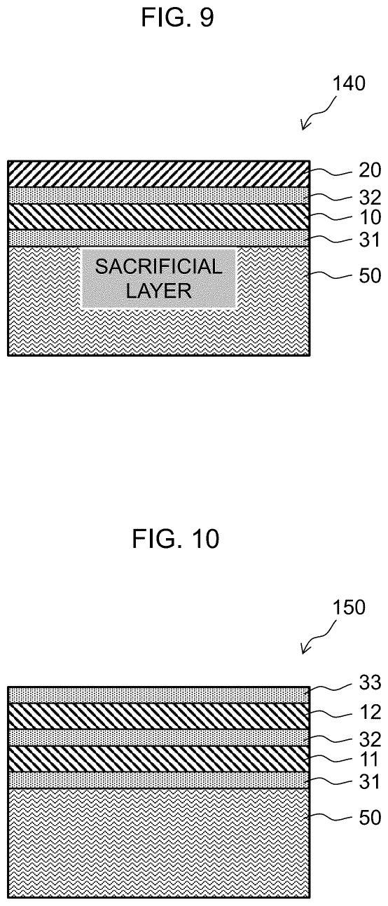

FIG. 5 is a schematic sectional view illustrating an overview configuration of a composite substrate according to a fifth embodiment of the present invention. A composite substrate 140 further includes an electrode layer 31 disposed between a support substrate 50 and a first piezoelectric layer 10 and an electrode layer 32 disposed between the first piezoelectric layer 10 and a second piezoelectric layer 20 as compared with the composite substrate 130 described in the fourth embodiment. The electrode layers 31 and 32 are constituted using a conductive material such as metal, for example, similarly to the electrode layer 30 in the composite substrate 110 described in the second embodiment. Note that the support substrate 50 may have a structure as in FIGS. 6, 7, 8, and 9 in the composite substrate 140. FIGS. 6 and 7 illustrate an example of a case where an opening portion is provided in the support substrate 50 in the composite substrate 140 according to the fifth embodiment of the present invention. FIG. 8 illustrates an example of a case where a hollow portion is provided in the support substrate 50 in the composite substrate 140 according to the fifth embodiment of the present invention. FIG. 9 illustrates an example of a case where a sacrificial layer to be removed in a later process is provided in the support substrate 50 in the composite substrate 140 according to the fifth embodiment of the present invention.

In the composite substrate 140, the support substrate 50 or the first piezoelectric layer 10 and the electrode layer 31 are directly bonded to each other, the first piezoelectric layer 10 or the second piezoelectric layer 20 and the electrode layer 32 are directly bonded to each other, and amorphous layers generated at the time of the bonding are formed at the bonding interfaces therebetween. Note that specific examples and bonding methods of the electrode layers 31 and 32 will be described later.

### (A-6) Sixth Embodiment

FIG. 10 is a schematic sectional view illustrating an overview configuration of a composite substrate according to a sixth embodiment of the present invention. A composite substrate 150 includes piezoelectric layers 11 and 12 that have a common polarization direction instead a first piezoelectric layer 10 and a second piezoelectric layer 20 and further includes an electrode layer 33 that is formed on a surface of the piezoelectric layer 12 as compared with the composite substrate 140 described in the fifth embodiment. The electrode layer 33 is constituted using a conductive material such as metal, for example, similarly to the electrode layer 30 in the composite substrate 110 described in the second embodiment.

In the composite substrate 150, a support substrate 50 or the piezoelectric layer 11 and an electrode layer 31 are directly bonded to each other and the piezoelectric layer 11 or the piezoelectric layer 12 and an electrode layer 32 are directly bonded to each other similarly to the composite substrate 140 described in the fifth embodiment, and amorphous layers generated at the time of the bonding are formed at bonding interfaces therebetween.

The composite substrates 100 to 150 described above in the embodiments are used as piezoelectric actuators which are, for example, MEMS devices. Note that although not illustrated in the drawings, the composite substrates 100 to 150 may further include arbitrary layers. Types, functions, numbers, combinations, arrangement, and the like of such layers may be appropriately set in accordance with purposes. For example, the composite substrates 100 to 140 may further include an electrode layer 33 that is disposed on the second piezoelectric layer 20 similarly to the composite substrate 150. The electrode layer 33 is provided with, for example, a wiring layer. Also, an electrode may be formed on an exposed surface of the first piezoelectric layer 10 in the composite substrates 100 to 120, or an electrode may be formed on an exposed surface of the first piezoelectric layer 10 formed by removing the support substrate 50 through etching or the like in the composite substrate 130, for example.

The composite substrates 100 to 150 may be manufactured into arbitrary appropriate shapes. In one embodiment, the composite substrates 100 to 150 may be manufactured in the form of so-called wafers. Also, the sizes of the composite substrates 100 to 150 may be appropriately set to wafer (substrate)diameters of 50 mm to 150 mm, for example, in accordance with purposes.

### A-1. Piezoelectric Layer

The first piezoelectric layer 10 and the second piezoelectric layer 20 (hereinafter, simply referred to as “piezoelectric layers”) are constituted by non-oriented polycrystalline bodies, for example. Also, as a representative example, the piezoelectric layers are constituted by sintered bodies. For example, grain boundaries are observed in the piezoelectric layers in TEM observation. It is possible to obtain the composite substrates 100 to 150 that include piezoelectric layers capable of achieving both size reduction and a piezoelectric property by employing such configurations. Specifically, since the piezoelectric layers may be formed alone, an internal stress does not occur due to interactions with other members at the time of the formation of the piezoelectric layers, for example, and it is thus possible to suppress deformation such as warpage. Also, options for a material constituting the piezoelectric layers increases by constituting the piezoelectric layers using non-oriented polycrystalline bodies, and it is possible to address diversified properties. Specifically, it is possible to finely adjust properties such as piezoelectric constants, dielectric constants, electromechanical coupling coefficients, and curie temperatures in accordance with needs. Furthermore, it is possible to form the piezoelectric layers at low costs, which may contribute to an improvement in reliability of the obtained composite substrates 100 to 150.

Here, “non-oriented” means that a c-axis orientation degree obtained by the Lotgering method is 80% or less, is preferably 60% or less, is more preferably 40% or less, is further preferably 20% or less, and is particularly preferably 10% or less. The c-axis orientation degree is an orientation degree F. (001) Of a (001) plane calculated using the following expressions from an XRD profile obtained by measurement using an X-ray diffraction apparatus.

$${F}_{( 001 )} = ( p - {p}_{0} ) / ( 1 - {p}_{0} ) \times 100$$

$$p = \sum I ( 001 ) / \sum I ( hk 1 )$$

$${p}_{0} = \sum {I}_{0} ( 001 ) / \sum {I}_{0} ( hk 1 )$$

(I and I₀ represent diffraction intensity, and p and po are calculated from a ratio between diffraction intensity derived from a c-axis diffraction plane (001) and diffraction intensity of a total diffraction plane (hk1); I and p are values obtained from an XRD profile of a piezoelectric film (piezoelectric substrate), and I₀ and po are values obtained from an XRD profile of a sample obtained by forming the piezoelectric film (piezoelectric substrate) into powder.)

As a material constituting the piezoelectric layer, an arbitrary appropriate ferroelectric body is used. A PZT (lead zirconate titanate)-based compound is preferably used. As the PZT-based compound, it is possible to use not only a two-component-based PZT (PbZrO3-PbTiO3) of lead titanate having a perovskite structure and lead zirconate but also a three-component-based PZT. The piezoelectric layers can contain the three-component-based PZT by constituting the piezoelectric layers by non-oriented polycrystalline bodies. It is possible to cause the obtained composite substrates 100 to 150 to address diversified properties by using the three-component-based PZT. Specifically, it is possible to finely adjust properties such as piezoelectric constants, dielectric constants, electromechanical coupling coefficients, and curie temperatures in accordance with needs.

An atomic ratio (Zr/Ti) between Zr and Ti contained in the piezoelectric layers is preferably 0.7 or more and 2.0 or less, and is more preferably 0.9 or more and 1.5 or less.

The three-component-based PZT is representatively expressed as ATiO3-PbZrO3-PbTiO3 or PbBO3-PbZrO3-PbTiO3, where A and B each represent an element other than Pb, Zr, and Ti. Examples of the element A contained in the third component in the three-component-based PZT include Li, Na, K, Bi, La, Ce, and Nd. Examples of the element B contained in the third component of the three-component-based PZT include Li, Cu, Mg, Ni, Zn, Mn, Co, Sn, Fe, Cd, Sb, Al, Yb, In, Sc, Y, Nb, Ta, Bi, W, Te, and Re. One of these may be used alone, or two or more kinds thereof may be used in combination.

A proportion of the third component with respect to a total of Zr, Ti, Pb, and the third component (the element A and/or the element B) contained in the piezoelectric layers, specifically, the atomic ratio of the third component/(Zr+Ti+Pb+ the third component) is preferably 0.05 or more and 0.25 or less, and is more preferably 0.10 or more and 0.20 or less.

The atomic ratio (proportion) can be obtained by composition analysis based on energy dispersive X-ray spectroscopy (EDX).

Other specific examples of the material constituting the piezoelectric layers include PMN-PT (Pb(Mg1/3Nb2/3)O3-PbTiO3), barium titanate (BaTiO3), lead titanate (PbTiO3), lead metaniobate (PbNb2O6), bismuth titanate (Bi4Ti3O12), KNN((K0.5Na0.5) NbO3), KNN-LN (((K0.5Na0.5) NbO3)—LiNbO3), and BT-BNT-BKT ((Bi0.5Na0.5) TiO3—(Bi0.5K0.5) TiO3-BaTiO3).

The piezoelectric layers may be any piezoelectric layers as long as they can be formed alone, and may be monocrystal bodies. In the case of monocrystal bodies, the piezoelectric layers are produced by slicing a monocrystal ingot. Specific examples of the monocrystal bodies include LiTaO3, LiNbO3, and crystal.

The thickness of the piezoelectric layers is, for example, greater than 0.2 μm, is preferably 0.3 μm or more, is more preferably 1 μm or more, and is further preferably 3 μm or more. In one embodiment, the thickness of the piezoelectric layers may be 5 μm or more, or may be 6 μm or more. With such a thickness, it is possible to obtain an actuator with large displacement driven at a low voltage, for example. In a case where the piezoelectric layers are formed through film formation such as sputtering as in the related art, for example, it is difficult to achieve such a thickness due to relationships of a film stress, productivity, and the like of the obtained piezoelectric layers. On the other hand, such a thickness can be set by constituting the piezoelectric layers by the non-oriented polycrystalline bodies as described above. Moreover, it is possible to obtain the composite substrates 100 to 150 that reduce occurrence of warpage and the like even with such a thickness by constituting the piezoelectric layers by the non-oriented polycrystalline bodies. On the other hand, the thickness of the piezoelectric layers is, for example, 200 μm or less, is preferably 150 μm or less, is more preferably 100 μm or less, is further preferably 50 μm or less, and is particularly preferably 20 μm or less. With such a thickness, it is possible to suppress disadvantages (for example, occurrence of cracking due to heating) occurring due to a difference in thermal expansion from the support substrate and to address a heating process (at 100° C. or higher, for example) in production of a piezoelectric device, for example. Specifically, it is possible to address mask formation using photolithography in production of a MEMS device.

As described above, the piezoelectric layers may be constituted by sintered bodies. The sintered bodies may be formed by an arbitrary appropriate method. In one embodiment, the sintered bodies can be formed by pressure-sintering ingredient powder. In a specific example, it is possible to form the sintered bodies by pressure-sintering ingredient powder mixed at a predetermined blending ratio or powder obtained by pulverizing ingredient powder mixed at a predetermined blending ratio into a predetermined particle diameter (for example, 0.1 μm to 10 μm) after calcination. As the pressure-sintering, an arbitrary appropriate method may be employed. Specifically, an HIP method, a hot-press method, or the like may be employed.

The piezoelectric layers can be obtained by performing working such as grinding and polishing on the sintered bodies (piezoelectric substrates) into a desired thickness, for example. In the formation of the piezoelectric layers, polarization processing is performed at an arbitrary appropriate timing. In one embodiment, a pair of electrodes are provided on mutually facing surfaces of the sintered bodies (piezoelectric substrates) formed into a plate shape, polarization processing is performed with an electric field in a direction from one electrode to the other electrode, and working such as grinding and polishing is performed thereon, thereby obtaining the piezoelectric layers.

Arithmetic mean roughness Ra of the piezoelectric layers after the polishing is preferably 2 nm or less, is more preferably 1 nm or less, and is further preferably 0.3 nm or less.

### A-2. Support Substrate

As the support substrate 50, an arbitrary appropriate substrate may be used. The support substrate 50 may be constituted by a monocrystal body or may be constituted by a polycrystalline body. Alternatively, the support substrate 50 may be constituted by metal. A material constituting the support substrate 50 is preferably selected from the group consisting of silicon, sialon, sapphire, cordierite, mullite, glass, quartz, crystal, alumina, stainless steel, an iron-nickel alloy (Alloy 42), and brass.

Silicon may be monocrystal silicon, polycrystalline silicon, or high-resistance silicon. Also, the support substrate 50 may be a silicon-on-insulator (SOI).

Sialon is representatively a ceramic obtained by sintering a mixture of silicon nitride and alumina and has, for example, a composition represented as Si6-wAlwOwN8-w. Specifically, sialon has a composition in which alumina is mixed in silicon nitride, and w in the formula denotes a mixing ratio of alumina. Preferably, w is 0.5 or more and 4.0 or less.

Sapphire is representatively a monocrystal body that has a composition of Al2O3, and alumina is a polycrystalline body that has a composition of Al2O3. Alumina is preferably light transmitting alumina.

Cordierite is representatively a ceramic that has a composition of 2Mg0.2Al2O3.5SiO2, and mullite is a ceramic that has a composition within a range from 3Al2O3.2SiO2 to 2Al2O3·SiO2.

In a case of utilization as a piezoelectric actuator, it is also possible to use a support substrate provided with an opening portion or a hollow portion. Examples are illustrated in FIGS. 6, 7, and 8. Moreover, it is also possible to use a support substrate provided with a sacrificial layer. An example is illustrated in FIG. 9. It is possible to reduce fracture failures at the time of production of the composite substrate by removing the sacrificial layer through etching after formation of the composite substrate. As the sacrificial layer, an arbitrary appropriate configuration may be employed in accordance with purposes. Examples of a material constituting the sacrificial layer include amorphous silicon, silicon, molybdenum, silicon oxide, aluminum oxide, a compound of these materials, and a mixture of these materials. Also, examples of a method of film formation for the sacrificial layer include sputtering, plating, and deposition. Examples of a method of etching the sacrificial layer include wet etching and dry etching.

As the thickness of the support substrate 50, an arbitrary appropriate thickness may be employed. The thickness of the support substrate 50 is, for example, 100 μm to 1000 μm.

### A-3. Bonding Layer

Examples of a material constituting the bonding layer 40 include silicon, tantalum oxide, niobium oxide, aluminum oxide, titanium oxide, and hafnium oxide. The thickness of the bonding layer 40 is, for example, 5 nm to 1 μm and is preferably 10 nm to 200 nm.

The bonding layer 40 is representatively constituted by an amorphous body. Specifically, the bonding layer 40 may be an amorphous layer. Constituting the bonding layer 40 by an amorphous body makes it easy to perform polishing, which will be described later, for example, and to obtain suitable surface roughness at a bonding surface.

The bonding layer 40 may be formed by an arbitrary appropriate method. For example, the bonding layer 40 may be formed by physical deposition such as sputtering, vacuum deposition, or ion beam assisted deposition (IAD), chemical deposition, or an atomic layer deposition (ALD) method. The film formation of the bonding layer 40 can be performed at a room temperature (25° C.) to 300° C., for example.

### A-4. Electrode Layers

Examples of materials used to constitute the electrode layers 30 to 33 include metal such as Pt, Au, Ti, Cr, Ni, Mo, Al, Ru, and SRO, and a compound and an oxide of these materials. One of these may be used alone, or two or more kinds thereof may be used in combination.

In one embodiment, materials constituting the electrode layers 30 to 33 are substantially the same. Specifically, the electrode layers 30 to 33 have substantially the same composition. In the composite substrate 140, for example, the electrode layer 31 is constituted by metal (for example, Ti), and the electrode layer 32 is constituted by metal (for example, Ti). Such a configuration can be employed by constituting the piezoelectric layers by non-oriented polycrystalline bodies. In a case where the piezoelectric layers are formed through film formation, for example, adjacent layers (electrodes) have a function as seed crystal layers of the piezoelectric layers and are constituted by a material that has a predetermined physical property (for example, a lattice constant). On the other hand, options for a material constituting the adjacent layers (electrodes) increases by constituting the piezoelectric layers by non-oriented polycrystalline bodies, and it is possible to select a material from a viewpoint of manufacturing efficiency and properties of the obtained composite substrate (piezoelectric element), for example.

The thickness of each of the electrode layers 30 to 33 that may function as layers in close contact with the adjacent layers is, for example, 1 nm or more and 100 nm or less, is preferably 3 nm or more and 50 nm or less, and is further preferably 5 nm or more and 20 nm or less.

The electrode layers 30 to 33 may be formed by an arbitrary appropriate method. For example, the electrode layers 30 to 33 may be formed by physical deposition such as sputtering, vacuum deposition, or ion beam assisted deposition (IAD). In one embodiment, the electrode layers 30 to 33 may be formed by performing sputtering using the same target (for example, a Ti target) under the same conditions. The film formation of the electrode layers 30 to 33 can be performed at a room temperature (25° C.) to 300° C., for example.

### A-5. Manufacturing Method

The composite substrates 100 to 150 can be obtained by bonding (directly bonding) the piezoelectric layers constituted by sintered bodies, for example, or bonding the piezoelectric layers and the support substrate 50.

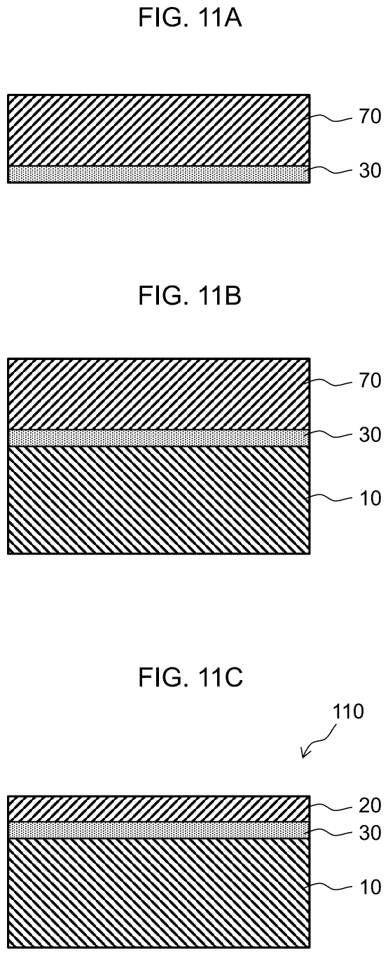

FIG. 11 is a diagram illustrating an example of a manufacturing process of the composite substrate 110 according to the second embodiment, as an example of manufacturing processes of the composite substrates 100 to 150. FIG. 11A illustrates a film formation process in the manufacturing process of the composite substrate 110. In the film formation process, the electrode layer 30 is formed through film formation on a surface of a piezoelectric substrate 70 that is a bulk sintered body after polarization processing.

FIG. 11B illustrates a bonding process in the manufacturing process of the composite substrate 110. In the bonding process, the electrode layer 30 formed on the piezoelectric substrate 70 in the film formation process in FIG. 11A and the first piezoelectric layer 10 after polarization processing which also acts as a support substrate are brought into contact with each other after bonding surfaces thereof are activated by arbitrary appropriate activation processing, and are then pressurized at an ordinary temperature, thereby achieving direct bonding. At this time, disposition of the piezoelectric substrate 70 and the first piezoelectric layer 10 is determined such that the polarization direction of the piezoelectric substrate 70 and the polarization direction of the first piezoelectric layer 10 are mutually opposite directions.

In one embodiment, an element (for example, argon) that constitutes gas to be used for the activation processing is contained near a bonding interface between the electrode layer 30 and the first piezoelectric layer 10. Specifically, an end portion of at least one of the electrode layer 30 and the first piezoelectric layer 10 facing each other via the bonding interface is an amorphous region (a region including an amorphous body; an amorphous layer) containing an element constituting gas to be used for the activation processing. The thickness of such an amorphous region is, for example, 2 nm to 30 nm. The concentration of argon in the amorphous region is, for example, 0.5 atm % to 30 atm %. Although a distribution state of argon in the amorphous region is not particularly limited, the concentration of argon increases toward the side of the bonding interface in the amorphous region, for example.

FIG. 11C illustrates a polishing process in the manufacturing process of the composite substrate 110. In the polishing process, the second piezoelectric layer 20 is formed by performing working such as grinding and polishing on the piezoelectric substrate 70 bonded to the first piezoelectric layer 10 via the electrode layer 30 in the bonding process in FIG. 11B to a desired thickness. The composite substrate 110 is thus manufactured.

In one embodiment, working such as grinding and polishing is performed on the piezoelectric substrate 70 such that the obtained thickness of the second piezoelectric layer 20 exceeds 0.2 μm. According to such an embodiment, it is possible to suppress occurrence of particle shedding of crystals constituting the second piezoelectric layer 20 and peeling of the second piezoelectric layer 20 without weakening a coupling force of the grain boundary of the obtained second piezoelectric layer 20 and a coupling force with the support substrate due to a working load.

Note that although FIG. 11 illustrates an example of the manufacturing process of the composite substrate 110 according to the second embodiment, the composite substrates described in the other embodiments can also be produced by a similar manufacturing process. However, since the first piezoelectric layer 10 and the second piezoelectric layer 20 are directly bonded in the composite substrate 100 according to the first embodiment, the film formation process in FIG. 11A is omitted. Also, the bonding layer 40 is formed through film formation instead of the electrode layer 30, the bonding layer 40 and the first piezoelectric layer 10 are directly bonded, and the amorphous layer is formed on the bonding interface therebetween in the film formation process in FIG. 11A for the composite substrate 120 according to the third embodiment.

Furthermore, the first piezoelectric layer 10 with a desired thickness is formed on the support substrate 50, and the amorphous layer is formed on the bonding interface between the support substrate 50 and the first piezoelectric layer 10 by performing the bonding process in FIG. 11B and the polishing process in FIG. 11C using the support substrate 50 and the piezoelectric substrate 70 for the composite substrate 130 according to the fourth embodiment. Thereafter, the second piezoelectric layer 20 with a desired thickness is formed on the first piezoelectric layer 10, and the amorphous layer is formed on the bonding interface between the first piezoelectric layer 10 and the second piezoelectric layer 20 by performing the bonding process in FIG. 11B and the polishing process in FIG. 11C again. At this time, in order for the polarization direction of the piezoelectric substrate 70 to form the second piezoelectric layer 20 and the polarization direction of the first piezoelectric layer 10 to become mutually opposite directions as described above, the disposition thereof is determined. However, since the support substrate 50 and the first piezoelectric layer 10 are directly bonded, and the first piezoelectric layer and the second piezoelectric layer 20 are directly bonded in the composite substrate 130 according to the fourth embodiment, the film formation process in FIG. 11A is omitted.

Also, the first piezoelectric layer 10 or the piezoelectric layer 11 with a desired thickness is formed on the support substrate 50 with the electrode layer 31 interposed therebetween, and the amorphous layer is formed on the bonding interface between the electrode layer 31 and the first piezoelectric layer 10 or on the bonding interface between the electrode layer 31 and the first piezoelectric layer 11 by performing the film formation process in FIG. 11A, the bonding process in FIG. 11B, and the polishing process in FIG. 11C using the support substrate 50 and the piezoelectric substrate 70 for the composite substrate 140 according to the fifth embodiment and the composite substrate 150 according to the sixth embodiment. Thereafter, the second piezoelectric layer 20 or the piezoelectric layer 12 with a desired thickness is formed on the first piezoelectric layer 10 or the piezoelectric layer 11 with the electrode layer 32 interposed therebetween, and the amorphous layer is formed on the bonding interface between the electrode layer 32 and the second piezoelectric layer 20 or on the bonding interface between the electrode layer 32 and the second piezoelectric layer 12 by performing the film formation process in FIG. 11A, the bonding process in FIG. 11B, and the polishing process in FIG. 11C again. At this time, in order for the polarization direction of the piezoelectric substrate 70 to form the second piezoelectric layer 20 and the polarization direction of the first piezoelectric layer 10 to become mutually opposite directions in the composite substrate 140 as described above, the disposition thereof is determined. On the other hand, the electrode layer 33 is further formed by performing the film formation process in FIG. 11A after the piezoelectric layer 12 is formed in the composite substrate 150.

In the composite substrates 100 to 150, the surface of each layer (specifically, the support substrate 50, the first piezoelectric layer 10, the second piezoelectric layer 20, the electrode layers 30 to 32, or the bonding layer 40) is a flat surface. Specifically, arithmetic mean roughness Ra of the surface of each layer is, for example, 5 nm or less, is preferably 2 nm or less, is more preferably 1 nm or less, and is further preferably 0.3 nm or less. Examples of a method of flattening the surface of each layer include chemical mechanical polishing (CMP) and mirror polishing by lap polishing.

At the time of the film formation process and the bonding process, it is preferable to clean the surface of each layer to remove a residue of an abrasive, for example. Examples of a cleaning method include wet cleaning, dry cleaning, and scrub cleaning. Among these, scrub cleaning is preferable because it is possible to simply and efficiently perform cleaning. Specific examples of the scrub cleaning include a method of cleaning by a scrub cleaning machine using a solvent (for example, a mixed solution of acetone and isopropyl alcohol (IPA)) after using a cleaning agent (for example, the Sunwash series manufactured by Lion Corporation).

The activation processing is representatively performed by irradiation with a neutral beam. Preferably, a neutral beam is generated using an apparatus such as an apparatus described in Japanese Patent Laid-Open No. 2014-086400, and irradiation with the beam is performed, thereby performing the activation processing. Specifically, a fast atom beam source of a saddle field type is used as a beam source, inert gas such as argon or nitrogen is introduced into a chamber, and a high voltage is applied from a DC power source to an electrode. In this manner, electrons move due to an electric field of the saddle field type generated between the electrode (positive pole) and a casing (negative pole), and beams of atoms and ions by the inert gas are generated. Since the ion beam is neutralized by a grid among the beams that have reached the grid, a beam of neutral atoms is emitted from the fast atom beam source. The voltage at the time of the activation processing through the beam irradiation is preferably 0.5 kV to 2.0 kV, and the current at the time of the activation processing through the beam irradiation is preferably 50 mA to 200 mA.

The contact and the pressurization of the bonding surfaces are preferably performed in a vacuum atmosphere. The temperature at this time is representatively an ordinary temperature. Specifically, the temperature is preferably 20° C. or higher and 40° C. or lower, and is more preferably 25° C. or higher and 30° C. or lower. The pressure to be applied is preferably 100 N to 20000 N.

Although the piezoelectric substrate 70 provided with the electrode layer 30 through film formation and the first piezoelectric layer 10 are bonded to obtain the composite substrate 110 in the example in FIG. 11, the present invention is not limited to such a mode. For example, the electrode layer 30 formed on the first piezoelectric layer 10 may be bonded to the piezoelectric substrate 70 after the electrode layer 30 is provided on the side of the first piezoelectric layer 10. The same applies to the other embodiments.

In the bonding process, at least one of the first piezoelectric layer 10 and the second piezoelectric layer 20 is bonded to another layer, and the amorphous layer may thus be formed on the bonding interface between the piezoelectric layer and another layer. Specifically, in the composite substrate 100 according to the first embodiment and the composite substrate 130 according to the fourth embodiment, the amorphous layers may be formed on the bonding interfaces between the first piezoelectric layers 10 and the second piezoelectric layers 20. Also, in the composite substrate 110 according to the second embodiment and the composite substrate 140 according to the fifth embodiment, the electrode layers 30 and 32 are disposed between the first piezoelectric layers 10 and the second piezoelectric layers 20, and the amorphous layers may be formed on the bonding interfaces between the first piezoelectric layers 10 or the second piezoelectric layers 20 and the electrode layers 30 and 32. Similarly, in the composite substrate 120 according to the third embodiment, the bonding layer 40 is disposed between the first piezoelectric layer 10 and the second piezoelectric layer 20, and the amorphous layer may be formed on the bonding interface between the first piezoelectric layer 10 or the second piezoelectric layer 20 and the bonding layer 40.

### EXAMPLE

Hereinafter, an example of a composite substrate with a piezoelectric layer directly bonded to a support substrate will be specifically described as an example for verifying the structure of the composite substrate according to the present invention. Note that the following procedure was performed at a room temperature unless particularly stated otherwise.

PbZr03 powder, PbTi03 powder, Nb2O5 powder, and Zno powder were stirred and mixed by a ball mill using water as a dispersant, and the obtained mixture was dried and then calcined in the atmosphere (at 900° C. for 2 hours). Thereafter, wet milling was performed again by the ball mill for 20 hours, thereby obtaining powder with particle diameters of about 1 μm. Then, the powder was press-molded, thereby obtaining a molded article.

The obtained molded article was subjected to pre-sintering in the atmosphere at 1250° C. for 2 hours. After the sintering, the molded article was cooled in the atmosphere, thereby obtaining a pre-sintered body. The obtained pre-sintered body was buried in a container filled with mixed powder of PbO and ZrO2, the container with a lid thereon was placed in an internal-heating high-temperature high-pressure furnace, the temperature was raised from a room temperature to 1100° C. for 4.5 hours, and hot isostatic press processing (HIP method) was performed thereon. Specifically, pressurization was performed up to 280 bar at 1000° C. and the pressure was raised from 280 bar to 600 bar for 1 hour after the point at which the temperature exceeded 1000° C. at the time of the raising of the temperature, the pre-sintered body was held at 1100° C. and 600 bar for 1 hour, and hot isostatic press processing was performed. A plate-shaped sintered body was thus obtained.

Electrodes were formed on the upper surface and the lower surface of the obtained sintered body, and polarization processing was performed by applying a predetermined voltage. Thereafter, beveling, grinding, and lap polishing were performed on the sintered body, thereby obtaining a wafer (piezoelectric substrate) that had a first surface and a second surface facing each other and had a diameter of 4 inches and a thickness of 500 μm.

The first surface of the obtained piezoelectric substrate was finished through chemical mechanical polishing (CMP) and was mirror-finished such that arithmetic mean roughness Ra became less than 2 nm. Here, the arithmetic mean roughness Ra was a value measured by an atomic force microscope (AFM) with a field of view of 10 μm×10 μm.

A Ti film with a thickness of 10 nm, a Pt film with a thickness of 100 nm, a Ti film with a thickness of 10 nm, and a silicon film with a thickness of 150 nm were formed in this order on the mirror-finished first surface of the piezoelectric substrate through sputtering. Thereafter, chemical mechanical polishing (CMP) was performed on the surface of the silicon film to obtain the arithmetic mean roughness Ra of 0.2 nm.

A silicon substrate (support substrate) that had an orientation flat portion and had a diameter of 4 inches and a thickness of 500 μm was prepared. Chemical mechanical polishing (CMP) was performed on the surface of the silicon substrate in advance, and the arithmetic mean roughness Ra was 0.2 nm.

Then, the piezoelectric substrate and the support substrate was directly bonded. Specifically, the surface (on the side of the silicon film) of the piezoelectric substrate and the surface of the support substrate were cleaned, both the substrates were then put into a vacuum chamber, the vacuum chamber was evacuated up to a 10-6 Pa level, and the surfaces of both the substrates were then irradiated with a fast atom beam (acceleration voltage of 1 kV, Ar flow rate of 27 sccm) for 120 seconds. After the irradiation, the surfaces of both the substrates irradiated with the beam were overlaid, and both the substrates were pressurized at 10000 N for 2 minutes and were bonded, thereby obtaining a bonded body.

Then, the second surface of the piezoelectric substrate in the obtained bonded body was ground and polished, thereby obtaining a composite substrate including a piezoelectric layer with a thickness of 10 μm.

### <Tem Observation>

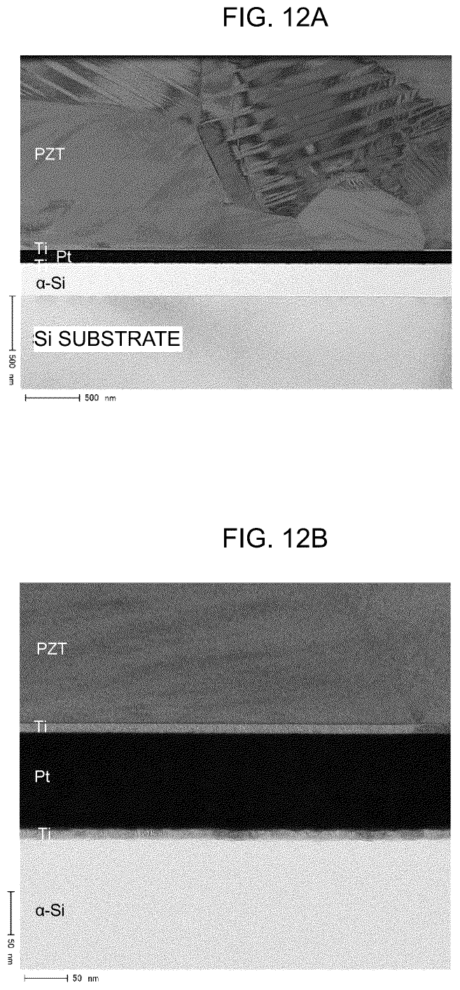

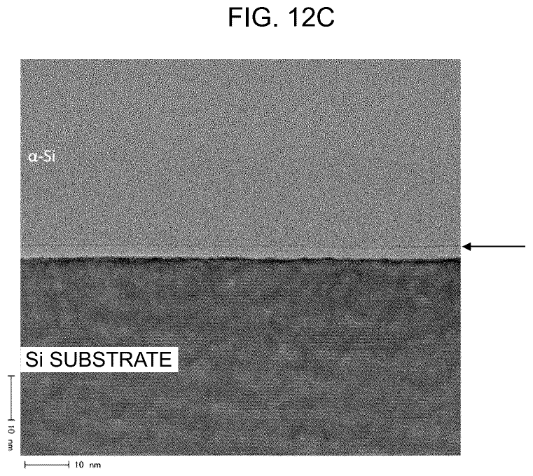

Transmission electron microscope (TEM) observation (50,000 folds, 400,000 folds, and 2,000,000 folds) of the section of the composite substrate produced as described above was performed. Observation photographs are shown in FIGS. 12A, 12B, and 12C. Note that observation samples were produced from the obtained composite substrate by the FIB method for the sectional TEM observation.

### <Edx Analysis>

In EDX analysis of the section of the composite substrate, the concentration of argon in the layer (the amorphous layer formed through the activation processing) indicated by the arrow in FIG. 12C was 3.0 atm %.

In the example, it was possible to confirm the structure of the composite substrate in which the piezoelectric layer with the thickness of 10 μm and the silicon substrate that was the support substrate were directly bonded with the metal films (the Ti films and the Pt film) that acted as the electrode layers and the silicon film that acted as the bonding layer interposed therebetween. In the composite substrate, an amorphous layer by the activation processing was formed on the bonding interface (the part indicated by the arrow in FIG. 12C) between the support substrate and the bonding layer. Therefore, it was possible to confirm that the composite substrates 100 to 150 described above were able to be produced through the similar processes.

According to the embodiments of the present invention described above, the following effects and advantages are achieved.

(1) Each of the composite substrates 100 to 150 includes the first piezoelectric layer 10 and the second piezoelectric layer 20 that is disposed to be stacked on the first piezoelectric layer, and the amorphous layer is formed on the bonding interface between at least one of the first piezoelectric layer 10 and the second piezoelectric layer 20 and another layer. In other words, at least one of the first piezoelectric layer 10 and the second piezoelectric layer 20 is directly bonded to another layer. It is thus possible to provide a composite substrate that has the piezoelectric layers capable of achieving both size reduction and a piezoelectric property.

(2) In each of the composite substrates 100 and 130, the amorphous layer is formed on the bonding interface between the first piezoelectric layer 10 and the second piezoelectric layer 20. In other words, the first piezoelectric layer 10 and the second piezoelectric layer 20 are directly bonded to each other. Also, each of the composite substrates 110, 120, 140, and 150 includes the electrode layer 30 or 32 or the bonding layer 40 that is disposed between the first piezoelectric layer 10 (piezoelectric layer 11) and the second piezoelectric layer 20 (piezoelectric layer 12), and the amorphous layer is formed on the bonding interface between the first piezoelectric layer 10 (piezoelectric layer 11) or the second piezoelectric layer 20 (piezoelectric layer 12) and the electrode layer 30 or 32 or the bonding layer 40. In other words, the first piezoelectric layer 10 (piezoelectric layer 11) or the second piezoelectric layer 20 (piezoelectric layer 12) and the electrode layer 30 or 32 or the bonding layer 40 are directly bonded to each other. Furthermore, each of the composite substrates 130, 140, and 150 includes the support substrate 50 that supports the first piezoelectric layer 10 (piezoelectric layer 11) and the second piezoelectric layer 20 (piezoelectric layer 12). It is thus possible to produce the composite substrates 100 to 150 with arbitrary layer structures.

(3) The support substrate 50 may be constituted by any of silicon, SOI, sialon, sapphire, cordierite, mullite, glass, quartz, crystal, alumina, stainless steel, an iron-nickel alloy (Alloy 42), and brass. It is thus possible to constitute the support substrate 50 by an arbitrary material in accordance with purposes.

(4) The thickness of at least one of the first piezoelectric layer 10 and the second piezoelectric layer 20 is preferably 50 μm or less. It is thus possible to achieve size reduction when piezoelectric actuators are constituted using the composite substrates 100 to 150.

(5) The polarization directions of the first piezoelectric layer 10 and the second piezoelectric layer 20 are mutually opposite directions. It is thus possible to form a composite substrate with a bimorph structure.

(6) Each of the first piezoelectric layer 10 and the second piezoelectric layer 20 may be constituted by any of PZT, PMN-PT, barium titanate, lead titanate, lead metaniobate, bismuth titanate, KNN, KNN-LN, BT-BNT-BKT, LiTaO3, LiNbO3, and crystal. Also, each of the first piezoelectric layer 10 and the second piezoelectric layer 20 may be constituted by a polycrystalline body. It is thus possible to constitute the first piezoelectric layer 10 and the second piezoelectric layer 20 by an arbitrary material in accordance with purposes.

Note that the present invention is not limited to the above embodiments and can be implemented using arbitrary components without departing from the gist thereof.

The aforementioned embodiments and modifications are only examples, and the present invention is not limited to the content thereof unless features of the present invention are lost. Also, although various embodiments and modifications have been described above, the present invention is not limited to the content thereof. Other aspects that are conceivable within the scope of the technical idea of the present invention are also included in the scope of the present invention.

What is claimed is:

1. A composite substrate comprising:
a first piezoelectric layer;
a second piezoelectric layer that is disposed to be stacked on the first piezoelectric layer; and
a support substrate that supports the first piezoelectric layer and the second piezoelectric layer,
wherein an amorphous layer is formed on a bonding interface between at least one of the first piezoelectric layer and the second piezoelectric layer and another layer,
the second piezoelectric layer, the first piezoelectric layer, and the support substrate are stacked in this order, and
each of the first piezoelectric layer and the second piezoelectric layer is constituted by a monocrystal body or a non-oriented polycrystalline body.

2. A composite substrate comprising:
a first piezoelectric layer; and
a second piezoelectric layer that is disposed to be stacked on the first piezoelectric layer,
wherein an amorphous layer is formed on a bonding interface between at least one of the first piezoelectric layer and the second piezoelectric layer and another layer,
polarization directions of the first piezoelectric layer and the second piezoelectric layer are mutually opposite directions, and
each of the first piezoelectric layer and the second piezoelectric layer is constituted by a monocrystal body or a non-oriented polycrystalline body.

3. The composite substrate according to claim 1,
wherein the amorphous layer is formed on a bonding interface between the first piezoelectric layer and the second piezoelectric layer.

4. The composite substrate according to claim 1, comprising:
an electrode layer or a bonding layer that is disposed between the first piezoelectric layer and the second piezoelectric layer,
wherein the amorphous layer is formed on a bonding interface between the first piezoelectric layer or the second piezoelectric layer and the electrode layer or the bonding layer.

5. The composite substrate according to claim 1,
wherein the support substrate is constituted by any of silicon, SOI, sialon, sapphire, cordierite, mullite, glass, quartz, crystal, alumina, stainless steel, an iron-nickel alloy (Alloy 42), and brass.

6. The composite substrate according to claim 1,
wherein at least one of the first piezoelectric layer and the second piezoelectric layer has a thickness of 50 μm or less.

7. The composite substrate according to claim 1,
wherein polarization directions of the first piezoelectric layer and the second piezoelectric layer are mutually opposite directions.

8. The composite substrate according to claim 1,
wherein each of the first piezoelectric layer and the second piezoelectric layer is constituted by a non-oriented polycrystalline body of any of PZT, PMN-PT, barium titanate, lead titanate, lead metaniobate, bismuth titanate, KNN, KNN-LN, and BT-BNT-BKT, or is constituted by a monocrystal body of any of LiTaO3, LiNbO3, and crystal.

9. A composite substrate comprising:
a first piezoelectric layer; and
a second piezoelectric layer that is disposed to be stacked on the first piezoelectric layer,
wherein at least one of the first piezoelectric layer and the second piezoelectric layer is directly bonded to another layer, and
each of the first piezoelectric layer and the second piezoelectric layer is constituted by a monocrystal body or a non-oriented polycrystalline body.

10. The composite substrate according to claim 9,
wherein the first piezoelectric layer and the second piezoelectric layer are directly bonded to each other.

11. The composite substrate according to claim 9, comprising:
an electrode layer or a bonding layer that is disposed between the first piezoelectric layer and the second piezoelectric layer,
wherein the first piezoelectric layer or the second piezoelectric layer and the electrode layer or the bonding layer are directly bonded to each other.

12. The composite substrate according to claim 1,
wherein at least one of the first piezoelectric layer and the second piezoelectric layer is constituted by a non-oriented polycrystalline body.

13. The composite substrate according to claim 12,
wherein the non-oriented polycrystalline body is a sintered body.
